(19) United States
(12) Patent Application Publication
(10) Pub. No.: US 2026/0293998 A1
(43) Pub. Date: Oct. 1, 2026

(54) A Method of Monitoring an Aerosol Generating System and an Aerosol Generating System

(71) Applicant: JT International SA, Geneva (CH)

(72) Inventors: Grzegorz Aleksander Pilatowicz, Grens (CH); Hajime Fujita, Geneva (CH)

(73) Assignee: JT International SA, Geneva (CH)

(21) Appl. No.: 19/477,370

(22) PCT Filed: Apr. 9, 2024
(86) PCT No.: PCT/EP2024/059612

§ 371 Date: Oct. 21, 2025

(30) Foreign Application Priority Data
Apr. 21, 2023 (EP) 23169174.2

(51) Int. Cl. A24F 40/53; A24F 40/90; G01R 31/367; G01R 31/382; G01R 31/392

(52) U.S. Cl. CPC A24F 40/53; A24F 40/90; G01R 31/367; G01R 31/382; G01R 31/392

(57) ABSTRACT

A method of monitoring an aerosol generating system comprising a plurality of energy storage devices, e.g., a Li-ion secondary battery and a capacitor or capacitor module adapted to supply power to generate an aerosol. The method includes applying an alternating current (AC) signal to the at least one energy storage device. At least one of voltage and current measurements obtained in response to the applied AC signal are used to estimate or determine one or more electrical parameters of the at least one energy storage device. The one or more electrical parameters are used to estimate or determine a condition of the at least one energy storage device.

### TECHNICAL FIELD

The present disclosure relates generally to a method of monitoring an aerosol generating system, and in particular to an aerosol generating system which may include an aerosol generating article which is adapted to be received in an aerosol generating device for generating an aerosol for inhalation by a user. The aerosol generating article may comprise an aerosol generating material or substrate.

The present disclosure is particularly applicable to a portable (hand-held) aerosol generating device.

### TECHNICAL BACKGROUND

Devices which heat, rather than burn, an aerosol generating material to produce an aerosol for inhalation have become popular with consumers in recent years. A commonly available reduced-risk or modified-risk device is the heated material aerosol generating device, or so-called heat-not-burn device. Devices of this type generate an aerosol or vapour by heating an aerosol generating material to a temperature typically in the range 150° C. to 300° C. This temperature range is quite low compared to an ordinary cigarette. Heating the aerosol generating material to a temperature within this range, without burning or combusting the aerosol generating material, generates a vapour which typically cools and condenses to form an aerosol for inhalation by a user of the device.

Such devices may use one of a number of different approaches to provide heat to the aerosol generating material. All approaches for heating the aerosol generating material require some sort of power source or energy storage device such as a battery or a capacitor (e.g., an electric double-layer supercapacitor), which may optionally be charged by an external power source. Some devices may have two or more energy storage devices that may be the same or different. Preferably, each energy storage device needs to be monitored in order to ensure reliable operation. Such monitoring may include monitoring a condition of each energy storage device such as the state of charge (SoC) or state of health (SoH), for example, which are directly related to device performance. The SoC is usually defined as the remaining charge of the energy storage device relative to the maximum charge of the device, and SoH is usually defined as the maximum charge of an aged energy storage device relative to the maximum charge of the energy storage device when new and is indicative of how the performance of the energy storage device has degraded over time. The SoH may also be defined in terms of other electrical parameters of the aged energy storage device such as its internal resistance or capacitance, for example, relative to the same electrical parameters of a new device. In this context, a new energy storage device means an energy storage device where the number of charge cycles is zero or very close to zero. Embodiments of the present disclosure seek to provide an aerosol generating system with active monitoring of one or more energy storage devices. This active monitoring may result in a more accurate determination of the actual operating condition of the energy storage device for more efficient operation and control of the aerosol generating system. A particular embodiment of the present disclosure is concerned with monitoring the condition of a detachable (or removable) energy storage device when it is electrically connected to the aerosol generating system—e.g., when it is inserted into an aerosol generating device. This may provide safe operation of the aerosol generating system because the condition of the energy storage device may be checked before the aerosol generating system is operated.

### SUMMARY OF THE DISCLOSURE

According to a first aspect of the present disclosure, there is provided a method of monitoring an aerosol generating system comprising a first energy storage device adapted to supply power to generate an aerosol, the method comprising monitoring a condition of the first energy storage device by:
supplying a direct current (DC) current to the first energy storage device to charge the first energy storage device;
applying an alternating current (AC) signal to the first energy storage device, wherein the AC signal is superimposed on the DC current being supplied to the first energy storage device;
using at least one of voltage and current measurements obtained in response to the applied AC signal to estimate or determine one or more electrical parameters of the first energy storage device; and
using the one or more electrical parameters to estimate or determine a condition of the first energy storage device.

The aerosol generating system may further comprise a second energy storage device. The DC current that is supplied to the first energy storage device may be supplied from the second energy storage device, i.e., the second energy storage device may be used to charge the first energy storage device or vice versa. The method may comprise monitoring a condition of the second energy storage device by:
supplying a DC current to the second energy storage device to charge the second energy storage device;
applying an AC signal to the second energy storage device, wherein the AC signal is superimposed on the DC current being supplied to the second energy storage device;
using at least one of voltage and current measurements obtained in response to the applied AC signal to estimate or determine one or more electrical parameters of the second energy storage device; and
using the one or more electrical parameter to estimate or determine a condition of the second energy storage device.

The AC signal may be applied to the first and second energy storage devices sequentially.

According to a second aspect of the present disclosure, there is provided a method of monitoring an aerosol generating system comprising a plurality of energy storage devices adapted to supply power to generate an aerosol, the method comprising monitoring a condition of at least one of the plurality of energy storage devices by:
applying an AC signal to the at least one energy storage device;
using at least one of voltage and current measurements obtained in response to the applied AC signal to estimate or determine one or more electrical parameters of the at least one energy storage device; and
using the one or more electrical parameters to estimate or determine a condition of the at least one energy storage device, e.g., an operating condition of the or each energy storage device which may be indicative of, or related to, device performance.

The aerosol generating system may comprise an aerosol generating device. The aerosol generating device is typically a hand-held, portable, device.

The aerosol generating device may be configured to heat an aerosol generating material or substrate, without burning the aerosol generating material, to volatise at least one component of the aerosol generating material and thereby generate a heated vapour which cools and condenses to form an aerosol for inhalation by a user of the aerosol generating device during a vaping session. The aerosol generating device may generate an aerosol in other ways, e.g., by using an ultrasonic transducer to atomise a liquid aerosol forming substrate.

In general terms, a vapour is a substance in the gas phase at a temperature lower than its critical temperature, which means that the vapour may be condensed to a liquid by increasing its pressure without reducing the temperature, whereas an aerosol is a suspension of fine solid particles or liquid droplets, in air or another gas. It should, however, be noted that the terms ‘aerosol’ and ‘vapour’ may be used interchangeably in this specification, particularly with regard to the form of the inhalable medium that is generated for inhalation by a user.

The aerosol generating device may comprise a heating chamber for receiving at least part of an aerosol generating material, and a heater configured to heat the aerosol generating material to generate an aerosol. The heater may be a low power thin film heater, printed heater etc. An induction heater may be preferred. An induction heater may comprise an induction coil and a susceptor and may be configured to heat the aerosol generating material. For example, the induction coil may be positioned adjacent an aerosol generating space or heating chamber of the aerosol generating device that is designed to receive the aerosol generating material, where the aerosol generating material is optionally part of an aerosol generating article or consumable that is received in the aerosol generating device in use. When the induction heater is used to heat the aerosol generating material, an alternating electromagnetic field is generated by the induction coil. A susceptor may be associated with the aerosol generating material, e.g., positioned adjacent to or embedded in the aerosol generating material, and may be part of the aerosol generating article or the aerosol generating device. The susceptor couples with the electromagnetic field and generates heat due to eddy currents and/or magnetic hysteresis, which heat is then transferred from the susceptor to the aerosol generating material. To generate the alternating electromagnetic field necessary for induction heating, the device may further comprise an inverter that is electrically connected to the induction coil. The same inverter may also be used to generate the AC signal that is applied to each energy storage device to estimate or determine its condition. In particular, the inverter may be selectively electrically connected to each energy storage device and the induction coil of the induction heater, e.g., by a suitable switching circuit.

The aerosol generating material may comprise any type of solid or semi-solid material. Example types of aerosol generating solids include powder, granules, pellets, shreds, strands, particles, gel, strips, loose leaves, cut filler, porous material, foam material or sheets. The aerosol generating material may comprise plant derived material and in particular, may comprise tobacco. It may advantageously comprise reconstituted tobacco, for example including tobacco and any one or more of cellulose fibres, tobacco stalk fibres and inorganic fillers such as calcium carbonate (CaCO₃).

Consequently, the aerosol generating device may be referred to as a “heated tobacco device”, a “heat-not-burn tobacco device”, a “device for vaporising tobacco products”, and the like, with this being interpreted as a device suitable for achieving these effects. The features disclosed herein are equally applicable to devices which are designed to vaporise any aerosol generating material, including a liquid material or substrate.

As mentioned briefly above, the aerosol generating material may form part of an aerosol generating article that is received in the aerosol generating device, for example by inserting the aerosol generating article into an aerosol generating space or heating chamber of the aerosol generating device. The aerosol generating article may include a filter segment, for example comprising cellulose acetate fibres, at a proximal end of the aerosol generating article. The filter segment may constitute a mouthpiece filter and may be in coaxial alignment with the aerosol generating material. One or more vapour collection regions, cooling regions, and other structures may also be included in some designs. For example, the aerosol generating article may include at least one tubular segment upstream of the filter segment. The tubular segment may act as a vapour cooling region. The vapour cooling region may advantageously allow the heated vapour generated by heating the aerosol generating material to cool and condense to form an aerosol with suitable characteristics for inhalation by a user, for example through the filter segment.

The aerosol generating material may comprise an aerosol-former. Examples of aerosol-formers include polyhydric alcohols and mixtures thereof such as glycerine or propylene glycol. Typically, the aerosol generating material may comprise an aerosol-former content of between approximately 5% and approximately 50% on a dry weight basis. In some embodiments, the aerosol generating material may comprise an aerosol-former content of between approximately 10% and approximately 20% on a dry weight basis, and possibly approximately 15% on a dry weight basis.

Upon being heated, the aerosol generating material may release volatile compounds. The volatile compounds may include nicotine or flavour compounds such as tobacco flavouring.

The aerosol generating material may be a liquid material or substrate and the device may comprise an atomising arrangement to atomise the liquid material or substrate, including without heating. The liquid material or substrate may also be heated.

The energy storage devices of the aerosol generating system may be the same or different. For example, one of the energy storage devices may be a lithium-ion secondary battery and another energy storage device may be a capacitor or capacitor module. Each capacitor may have any suitable construction, but in a preferred embodiment may be an electric double-layer supercapacitor. A capacitor may have a higher power density than a conventional power source such as a battery. Each energy storage device may be charged by an external power source such as a universal serial bus (USB) charger or a portable charging device, for example.

Each energy storage device may have any suitable construction for use in an aerosol generating device and is adapted to supply power to generate an aerosol.

Each energy storage device may comprise an electrolyte, a pair of electrodes and a porous separator between the electrodes. The pair of electrodes typically comprises a positive electrode (or cathode) and a negative electrode (or anode). The AC signal may be applied across the positive electrode and the negative electrode. The electrodes and the separator are immersed in the electrolyte. Each energy storage device may comprise a positive terminal electrically connected to the positive electrode and a negative terminal electrically connected to the negative electrode. The positive and negative terminals allow each energy storage device to be electrically connected to an external circuit. At least one of the energy storage devices may be detachable or removable where its positive and negative terminals can be in electrical contact with corresponding fixed terminals of an external circuit of the aerosol generating device when it is physically connected to the device, for example. Such a detachable or removable configuration may be beneficial because it allows a degraded or discharged energy storage device to be removed and replaced with a new energy storage device, e.g., an energy storage device where the number of charge cycles is zero or very close to zero.

In the case of a capacitor, electrical charge is stored in the electrical field between the electrodes and the capacitance is a function of the surface area of the electrodes, the distance between them, and the dielectric constant of the separator material. When the capacitor is charged by an external circuit that is electrically connected to the pair of electrodes, cations in the electrolyte migrate toward the negative electrode and the anions migrate to the positive electrode, while the electrons travel through the external circuit from the negative to the positive electrode. Two layers of charge with opposite polarity (an electric double-layer) are therefore formed at the interfaces with the electrodes. When charging finishes, positive electric charges on the positive electrode and anions in the electrolyte attract each other while negative electric charges on the negative electrode and cations in the electrolyte attract each other in order to stabilize the double layers on the electrodes. A stable voltage is generated. When the capacitor is discharged, the reverse processes happen.

In the case of a lithium-ion secondary battery, for example, during charging, the electrolyte carries positively charged lithium ions from the positive electrode to the negative electrode through the separator and electrons travel through the external circuit from the negative electrode to the positive electrode. When the lithium-ion secondary battery is discharged, lithium ions embedded in the negative electrode are released and move back to the positive electrode and electrons travel through the external circuit from the positive electrode to the negative electrode.

Each electrode may comprise at least one carbon-based electrode layer, for example, a layer of porous charcoal material or activated carbon which has a high specific surface area per volume and compatibility with the proposed electrolyte. In the case of a lithium-ion secondary battery, the positive electrode may include lithium metal oxide (e.g., lithium cobalt oxide (LiCoO₂)) or other suitable material and the negative electrode may include graphite, for example.

Each electrode may further comprise a current collector, which may comprise a metal foil layer, for example, an aluminium foil layer. Each current collector may encourage electron travelling via the external circuit. A carbon-based electrode layer may be positioned adjacent one or both sides of a current collector. Each carbon-based electrode layer may be formed as a coating. Such electrodes may be manufactured relatively easily and cheaply using materials that are already known to be used in aerosol generating articles. Each current collector may encourage electron travelling via the external circuit.

The separator must provide dielectric separation between the pair of oppositely charged electrodes. The separator also stores electrolyte in its pores and permits the passage of cations and anions during the charging and discharging processes. The separator may comprise any suitable material.

An AC signal may be applied to one of the energy storage devices when it is being charged by another one of the energy storage devices. For example, the AC signal may be superimposed on a discharging current that is supplied from one energy storage device to another energy storage device to charge it. This means that the condition of the at least one energy storage device may be estimated or determined entirely by the aerosol generating device without the need for any external components.

The method may further comprise operating the aerosol generating system in a heating mode and a non-heating mode. The AC signal may be applied to the at least one energy storage device (e.g., the first energy storage device) when the system is in the non-heating mode. For example, if the aerosol generating device comprises an aerosol generator such as a heater that is configured to heat an aerosol generating material or substrate to produce an aerosol, the AC signal may be applied at the end of a vaping session when the heater has been switched off but the aerosol generating system is still operational. The aerosol generator may be electrically disconnected from the at least one energy storage device by opening a switching device such as a semiconductor switch, for example. If the aerosol generating system is configured to generate an aerosol in other ways, e.g., by using an ultrasonic transducer to atomise a liquid aerosol forming substrate, the AC signal may be applied to the at least one energy storage device when the aerosol generator is not being operated. The condition of the at least one energy storage device, and in particular its output voltage, for example, may be more stable in the non-heating mode than in the heating mode. Applying the AC signal to the at least one energy storage device when the aerosol generating system is in the non-heating mode may therefore allow the condition of the at least one energy storage device to be estimated or determined more accurately.

Voltage measurements may be provided by a voltage sensing circuit that may comprise a voltage divider circuit, for example. Current measurements may be provided by a current sensing circuit that may comprise a current sensing amplifier or other suitable current sensor. These voltage and current sensing circuits allow the condition of the at least one energy storage device to be estimated or determined reliably and at low cost.

The method may further comprise monitoring a condition of each energy storage device of the plurality of energy storage devices by:
applying an AC signal to the respective energy storage device;
using at least one of voltage and current measurements obtained in response to the applied AC signal to estimate or determine one or more electrical parameters of the respective energy storage device; and
using the one or more electrical parameters to estimate or determine a condition of the respective energy storage device.

The AC signal is preferably applied to each energy storage device sequentially. In other words, an AC signal may be applied to a first energy storage device so that a condition of the first energy storage device may be estimated or determined, and an AC signal may then be applied to a second energy storage devices so that a condition of the second energy storage device may be estimated or determined. An AC signal may continue to be sequentially applied if there are three or more energy storage devices. The AC signal that is applied to each energy storage device may be the same or different, e.g., the applied AC signals may be swept across the same or different frequency ranges or may use one or more frequencies that are the same or different.

According to a third aspect of the present disclosure, there is provided a method of monitoring a detachable (or removable) energy storage device in response to the detachable energy storage device being electrically connected to an aerosol generating system for the first time by:
applying an AC signal to the connected energy storage device;
using at least one of voltage and current measurements obtained in response to the applied AC signal to estimate or determine one or more electrical parameters of the energy storage device; and
using the one or more electrical parameters to estimate or determine an initial condition of the energy storage device.

Normal operation of the aerosol generating system may be permitted only if the condition of the energy storage device is found to be within normal limits. This may improve the safety of the aerosol generating system by quickly identifying a possible fault with the energy storage device immediately after it has been electrically connected to the aerosol generating system—e.g., by inserting it into an aerosol generating device that forms part of the aerosol generating system. If the condition of the energy storage device is not within normal limits, further operation of the aerosol generating system may be prevented and/or the user may be notified, for example.

The method may further comprise supplying a DC current to the just-connected energy storage device. The AC signal may be superimposed on the DC current.

According to a fourth aspect of the present disclosure, there is provided an aerosol generating system comprising:
a first energy storage device;
an inverter electrically connected to the first energy storage device and configured to apply an AC signal to the first energy storage device;
a superimposing circuit electrically connected to the inverter and the first energy storage device, wherein the superimposing circuit is configured to superimpose the AC signal on a DC current that is supplied to the first energy storage device to charge the first energy storage device; and
a controller configured to:
   use at least one of voltage and current measurements obtained in response to the applied AC signal to estimate or determine one or more electrical parameters of the first energy storage device; and
   use the one or more electrical parameters to estimate or determine a condition of the first energy storage device.

The aerosol generating system may further comprise a second energy storage device. The inverter may be electrically connected to the second energy storage device and may be configured to apply an AC signal to the second energy storage device. The superimposing circuit may be electrically connected to the second energy storage device and may be configured to superimpose the AC signal on a DC current that is supplied to the second energy storage device.

According to a fifth aspect of the present disclosure, there is provided an aerosol generating system comprising:
a plurality of energy storage devices;
an inverter electrically connected to each energy storage device and configured to apply an AC signal to at least one of the plurality of energy storage devices; and
a controller configured to:
   use at least one of voltage and current measurements obtained in response to the applied AC signal to estimate or determine one or more electrical parameters of the at least one energy storage device; and use the one or more electrical parameters to estimate or determine a condition of the at least one energy storage device.

The aerosol generating system may further comprise a superimposing circuit electrically connected to the inverter and each energy storage device. The superimposing circuit may be configured to superimpose the AC signal on a DC current (e.g., a DC charging current) that is supplied by one of the energy storage devices to charge another one of the energy storage devices. The AC signal may also be superimposed on a DC current that is supplied by an external power source and used to charge the at least one of the energy storage devices. The aerosol generating system may further comprise a first switching circuit electrically connected between the superimposing circuit and each energy storage device (e.g., the first and second energy storage devices). The first switching circuit may be configured to selectively connect the output of the superimposing circuit to one of the energy storage devices. The first switching circuit may include an input terminal and two or more output terminals, each output terminal being selectively electrically connected to the positive terminal of a respective energy storage device. The first switching circuit may be controlled by the controller, e.g., in response to a select signal which selects between the output terminals. The single superimposing circuit may selectively output the superimposed AC signal to the respective energy storage device by means of the first switching circuit. This means that there is no need to provide a separate superimposing circuit for each energy storage device and the electrical circuit of the aerosol generating device is kept as simple as possible. A voltage sensing circuit may also be configured to measure the voltage across each energy storage device (e.g., across the first or second energy storage device) when the AC signal is applied. The voltage sensing circuit may be electrically connected between the output of the superimposing circuit and the first switching circuit. The voltage sensing circuit may comprise a voltage divider circuit. Multiple voltage sensing circuits are not needed even if the AC signal is applied to respective energy storage devices.

The first switching circuit may comprise a single-pole double-throw switching circuit.

A current sensing circuit may be configured to measure the current through each energy storage device (e.g., through the first or second energy storage device) when the AC signal is applied. The current sensing circuit may include a shunt resistor and a current sensing amplifier electrically connected with the shunt resistor. The aerosol generating system may further comprise a plurality of second switching circuits. Each second switching circuit may be electrically connected to a respective energy storage device (e.g., a respective one of the first and second energy storage devices) and configured to selectively connect the negative terminal of the respective energy storage device (e.g., the respective one of the first and second energy storage devices) directly to ground when the energy storage device is being discharged, or to ground via the shunt resistor of the current sensing device when the energy storage device is being charged and the AC signal is applied. Each second switching circuit may include an input terminal and two output terminals, one output terminal being electrically connected to the ground connection of the current sensing circuit and the other output terminal being electrically connected to one end of the shunt resistor. The other end of the shunt resistor is electrically connected to ground. The input terminal of each second switching circuit may be electrically connected to the negative terminal of the respective energy storage device. A single current sensing circuit can be selectively connected to each of the energy storage devices by means of the second switching circuits. This means that multiple current sensing circuits are not needed even if the AC signal is applied to respective energy storage devices. It also minimises the number of terminals or pins of the controller that are utilised. Each second switching circuit may be controlled by the controller, e.g., in response to a select signal which selects between the output terminals. A common select signal may be provided to the first switching circuit and each second switching circuit to provide coordinated switching control. The first and second switching circuits may be switched so that the first energy storage device is discharged to charge the second energy storage device through the superimposing circuit and vice versa. The second switching circuits may be controlled so that negative terminal of the energy storage device being discharged is electrically connected directly to ground and the negative terminal of the energy storage device being charged is electrically connected to the shunt resistor so that current measurements may be obtained by the current sensing circuit when the AC signal is applied.

Each of the second switching circuits may comprise a single-pole double-throw switching circuit.

The energy storage devices, inverter, controller, superimposing circuit, first switching circuit, voltage sensing circuit, current sensing circuit, and second switching circuits may be part of an aerosol generating device as described above.

According to a sixth aspect of the present disclosure, there is provided an aerosol generating system comprising:
an inverter electrically connectable to a detachable (or removable) energy storage device; and
a controller configured to:
   control the inverter to apply an AC signal to the energy storage device in response to it being electrically connected to the aerosol generating system for the first time;
   use at least one of voltage and current measurements obtained in response to the applied AC signal to estimate or determine one or more electrical parameters of the energy storage device; and
   use the one or more electrical parameters to estimate or determine an initial condition of the energy storage device.

The aerosol generating system may comprise a detection circuit configured to detect when the energy storage device is electrically connected to the aerosol generating system—e.g., to an external circuit of an aerosol generating device that forms part of the aerosol generating system. The controller may control the inverter to apply the AC signal to the energy storage device in response to an output of the detection circuit.

The aerosol generating system may comprise a superimposing circuit electrically connected to the inverter and electrically connectable to the energy storage device. The superimposing circuit may be configured to superimpose the AC signal on a DC current that is supplied to the energy storage device, e.g., from a second energy storage device of the aerosol generating system.

For each of the aspects of the present disclosure described above, the one or more electrical parameters of the or each energy storage device (e.g., the first or second energy storage device) may be estimated or determined based on the frequency dependency of the dielectric material of each energy storage device. For example, the one or more electrical parameters may be estimated or determined using a frequency response plot (i.e., a Nyquist or Cole-Cole plot). The frequency of the applied AC signal may be swept as a parameter, resulting in a plot based on frequency. This is described in more detail below with reference to FIG. 5, which shows an example of a Nyquist plot and an equivalent electrical circuit of an energy storage device, e.g., a lithium-ion secondary battery or a capacitor such as an electric double-layer capacitor. The equivalent electrical circuit includes an interface capacitance C_{if}, a solution resistance (or ohmic internal resistance) Rₛₒₗ, a charge transfer resistance R_{ct}, and a diffusion resistance (or Warburg resistance) Z_{W} that on the Nyquist plot appears as a diagonal line with a slope of 45 degrees. It will be understood that the Nyquist plot shown in FIG. 5 may be considered to be an idealised frequency response that is intended only to illustrate the electrical parameters of the energy storage device. In practice, the Nyquist plot derived for an actual energy storage device may deviate quite significantly from this idealised frequency response depending on practical factors such as the frequency points that are covered, including minimum and maximum frequency values, the physical design or construction of the energy storage device, temperature, device aging etc.

The applied AC signal may have a frequency that is in a preferred frequency range. For example, the frequency range may be from about 1 mHz to about 1 kHz. A wide frequency range may be beneficial because it may allow a more precise measurement of impedance, but it may also increase measurement duration. The preferred frequency range may be a compromise between these competing factors. The frequency may be swept across substantially the whole of the frequency range or across one or more narrower frequency ranges. For example, the frequency response plot may be constructed by focusing on one or more narrower frequency ranges such as a first frequency range between about 500 Hz and about 1 kHz—which may provide an indication of the solution resistance—a second frequency range between about 1 Hz and about 100 Hz—which may provide an indication of the charge transfer resistance and focus on the semi-circular part of the Nyquist plot shown in FIG. 5—and a third frequency range of less than about 1 Hz—which may provide an indication about diffusion resistance. The frequency of the applied AC signal may be swept one or more times over the preferred frequency range(s). Alternatively, one or more preferred frequencies may be used, e.g., one or more frequencies within each of the narrower frequency ranges mentioned above. It may be preferred that at least two frequencies within the second frequency range (i.e., about 1 Hz to about 100 Hz) are used to improve accuracy. As will be understood by one of ordinary skill in the art, measured values at the one or more preferred frequencies may be used to construct a simplified frequency response plot, e.g., a Nyquist plot where the diffusion resistance is omitted. One or more values of each electrical parameter may be used to estimate or determine the condition of each energy storage device. Alternatively, the condition of each energy storage device may be estimated or determined using all or part of the complete or simplified frequency response plot.

In one example, the voltage and current measurements obtained in response to the AC signal being applied to a particular energy storage device may be used to estimate or determine one or more values of the interface capacitance C_{if} where each value may then be compared against one or more thresholds to estimate or determine a condition of the energy storage device. For example, the interface capacitance C_{if} will normally decrease as the energy storage device degrades with age and if the interface capacitance C_{if} is below a first threshold it may indicate that the energy storage device needs to be replaced and if it is below a second threshold, that is lower than the first threshold, it may indicate that the energy storage device is not suitable for operation and that the aerosol generating system should be disabled or that its subsequent operation should be prevented. An appropriate notification may be provided to the user. One or more values of the solution resistance Rₛₒₗ and/or R_{ct} may also be compared against one or more thresholds in a similar manner. The one or more values of the electrical parameter or the complete or simplified frequency response plot may be compared against one or more corresponding values or plots obtained previously—e.g., at the conclusion of earlier vaping sessions. This comparison between values or plots obtained at different times may be used to estimate or determine the condition of the energy storage device as a function of time. This may allow the degradation of each energy storage device, or other conditions that are directly related to device performance, to be accurately monitored.

One or more values of the electrical parameters—e.g., the interface capacitance C_{if}, the solution resistance (or ohmic internal resistance) Rₛₒₗ, and the charge transfer resistance R_{ct}—may be used to estimate or determine the charge of the energy storage device using a known relationship. The charge may be used to estimate or determine a condition of the energy storage device such as the state of charge (SoC) or state of health (SoH), for example. For example, the SoC might be estimated or determined from the charge of the energy storage device relative to a stored value of the maximum charge of the device. If the charge is the maximum charge, i.e., the energy storage device is substantially fully-charged when the AC signal is applied, the SoH might be estimated or determined from the maximum charge relative to a stored value of the maximum charge of the energy storage device. The stored value of the maximum charge may be obtained when the energy storage device is new. For example, if the aerosol generating system utilises a detachable or removable energy storage device, the stored value of the maximum charge may be obtained when a new energy storage device is first electrically connected to the aerosol generating system. The SoH of the energy storage device may also be defined in terms of other electrical parameters of the aged energy storage device such as its internal resistance or capacitance, for example, relative to a stored value of the same electrical parameters of a new energy storage device.

The interface capacitance C_{if} of an energy storage device may be estimated or determined from:

$${C}_{if} = \frac{1}{2 π f \cdot \vert {Z}^{″} \vert}$$

where f is the frequency of the applied AC signal (f=ω/2π where ω is the angular frequency) and Z″ is the imaginary part of the complex impedance. The interface capacitance C_{if} may be estimated or determined with reference to the frequency of the applied AC signal f once the imaginary part of the complex impedance Z″ is obtained.

The charge transfer resistance R_{ct} of an energy storage device may be estimated or determined from:

$${R}_{c t} = \frac{1}{( {ω}_{max} \cdot {C}_{if} )}$$

where ωₘₐₓ is estimated or determined with reference to the frequency response plot, i.e., from the real and imaginary parts of the complex impedance Z′ and Z″.

### BRIEF DESCRIPTION OF THE DRAWINGS

FIG. 1 is a diagrammatic view of an example of an aerosol generating system comprising an aerosol generating device and an aerosol generating article;

FIG. 2 is a schematic representation of an example of an electrical circuit of the aerosol generating device;

FIGS. 3 and 4 are schematic representations of the example of the electrical circuit of FIG. 2 showing different steps of condition monitoring;

FIG. 5 is a schematic diagram of an example of a Nyquist plot and an equivalent electrical circuit of an energy storage device;

FIG. 6 is a schematic diagram of examples of Nyquist plots taken at different times.

### DETAILED DESCRIPTION OF EMBODIMENTS

Embodiments of the present disclosure will now be described by way of example only and with reference to the accompanying drawings.

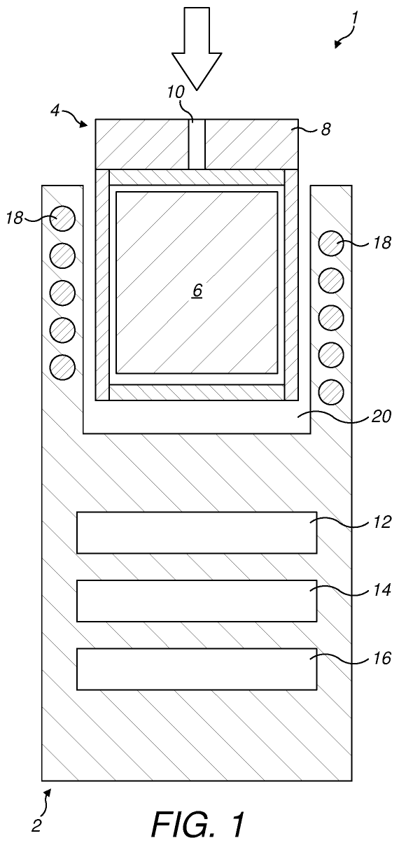

Referring initially to FIG. 1, there is shown diagrammatically an example of an aerosol generating system 1 including an aerosol generating device 2 and an aerosol generating article 4.

The aerosol generating article 4 may be generally cylindrical and include aerosol generating material 6. At the proximal end, the aerosol generating article 4 includes a mouthpiece 8 having an outlet 10 through which a user may inhale an aerosol that is generated by heating the aerosol generating material 6.

The aerosol generating device 2 includes an electrical circuit 12, a first energy storage device 14 such as a battery (e.g., a lithium-ion secondary battery), and a second energy storage device 16 such as a capacitor or capacitor module (e.g., one or more electric double-layer capacitors).

The aerosol generating device 2 may optionally include one or more heaters or other aerosol generators. The aerosol generating device 2 shown in FIG. 1 includes an induction heater with an induction coil 18 that is arranged adjacent an aerosol generating space or heating chamber 20 for heating the aerosol generating material 6 when the aerosol generating article 4 is inserted in the aerosol generating device 2. The aerosol generating article 4 may include one or more susceptors (not shown) that couple with the electromagnetic field and generate heat due to eddy currents and/or magnetic hysteresis, which heat is then transferred from the susceptor to the aerosol generating material 6. Alternatively, the aerosol generating device 2 may include one or more susceptors (not shown). It will be readily understood that other aerosol generators may be used, including those that are configured to generate an aerosol without heating, e.g., by using an ultrasonic transducer to atomise a liquid aerosol forming substrate.

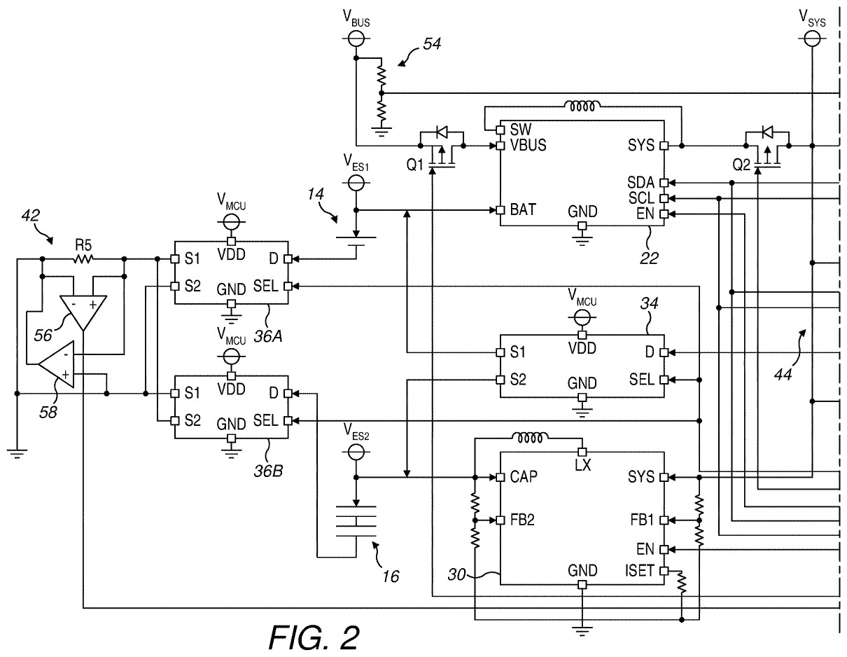

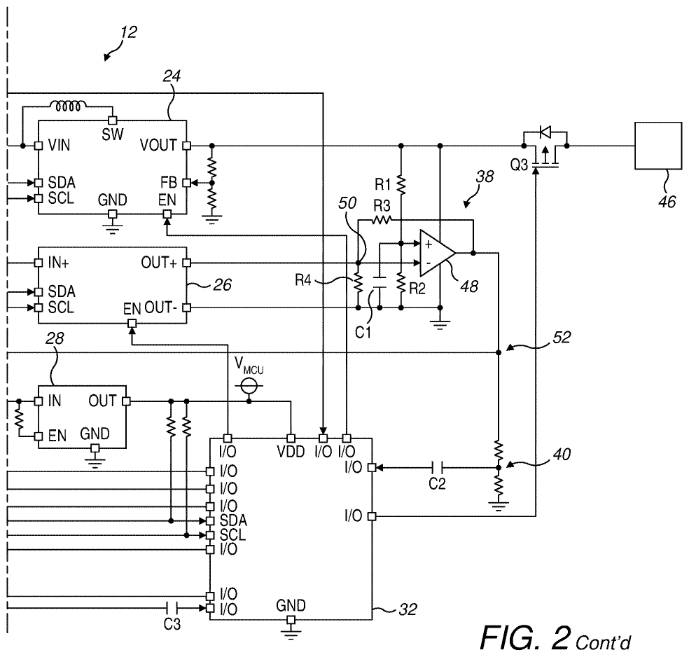

An example of an electrical circuit 12 is shown in FIG. 2. The electrical circuit 12 includes:
a charging circuit 22,
a DC/DC converter 24,
an inverter 26,
a low-dropout (LDO) regulator 28,
a reversible buck/boost regulator 30,
a microcontroller unit (MCU) 32,
a first switching circuit 34,
a pair of second switching circuits 36A, 36B,
a superimposing circuit 38,
a voltage sensing circuit 40, and
a current sensing circuit 42.

The charging circuit 22, DC/DC converter 24, inverter 26, LDO regulator 28, reversible buck/boost regulator 28, MCU 32, first switching circuit 34, and the pair of second switching circuits 36A, 36B may be implemented as integrated circuits.

The charging circuit 22 includes:
an input terminal (labelled “VBUS”) electrically connectable to an external power source (not shown) by means of a first semiconductor switch Q1,
a battery terminal (labelled “BAT”) electrically connected to the positive terminal of the first energy storage device 14, i.e., the lithium-ion secondary battery,
a system terminal (labelled “SYS”) electrically connected to a system bus 44 by means of a second semiconductor switch Q2,
a switching node terminal (labelled “SW”) electrically connected to the system terminal by means of an inductor,
a ground terminal (labelled “GND”) electrically connected to ground,
a serial data terminal (labelled “SDA”) and a serial clock terminal (labelled “SCL”) that are electrically connected to corresponding terminals of the MCU 32, and
an enable terminal (labelled “EN”) electrically connected to a first input/output terminal (labelled “I/O”) of the MCU 32 and which allows the MCU 32 to enable charging of the first energy storage device 14 from the external power source (not shown).

The charging circuit 22 may be used to charge the first energy storage device 14 from the external power source (e.g., a universal serial bus (USB) charger or portable charging device, not shown) and to provide an output voltage at the system terminal to the system bus 44. The output voltage at the system terminal of the charging circuit 22 may be provided by the external power source (not shown) and/or the first energy storage device 14 that are respectively electrically connected to the input terminal and the battery terminal of the charging circuit 22. The charging circuit 22 may allow the external power source (not shown) to charge the first energy storage device 14 and provide an output voltage at the system terminal at the same time. For example, it may be possible to use the external power source (not shown) to simultaneously charge the first energy storage device 14 and the second energy storage device 16—in the latter case through the system bus 44 and the reversible buck/boost regulator 30 described in more detail below.

The DC/DC converter 24 typically operates as a boost (or step-up) converter and converts the DC input voltage from the system bus 44 into a suitable boosted DC output voltage. The DC/DC converter 24 includes:
a voltage input terminal (labelled “VIN”) electrically connected to the system bus 44,
a switching node terminal (labelled “SW”) electrically connected to the voltage input terminal by means of an inductor,
a voltage output terminal (labelled “VOUT”) electrically connected to the induction heater 46 (or other suitable aerosol generator) by means of a third semiconductor switch Q3,
a serial data terminal (labelled “SDA”) and a serial clock terminal (labelled “SCL”) that are electrically connected to corresponding terminals of the MCU 32,
a feedback terminal (labelled “FB”) which receives a DC output voltage feedback, and
an enable terminal (labelled “EN”) electrically connected to a second input/output terminal (labelled “I/O”) of the MCU 32 and which allows the MCU 32 to enable and disable operation of the first DC/DC converter 24.

The reversible buck/boost regulator 30 may operate in a buck (or step-down) mode or a boost (or step-up) mode. When the system voltage (labelled “V_{SYS}”) on the system bus 44 is above a minimum operating voltage, the reversible buck/boost regulator 30 will typically operate in a buck mode to charge the second energy storage device 16 from the system bus 44 until it is fully charged. If the voltage on the system bus 44 is removed, the reversible buck/boost regulator 30 typically operates in a boost mode and prevents the system voltage from dropping below the minimum operating voltage by discharging the second energy storage device 16 to the system bus 44. The reversible buck/boost regulator 30 includes:
a capacitor terminal (labelled “CAP”) electrically connected to the positive terminal of the second energy storage device 16, i.e., the capacitor module,
a switching node terminal (labelled “LX”) electrically connected to the capacitor terminal by means of an inductor,
a system terminal (labelled “SYS”) electrically connected to the system bus 44,
a ground terminal (labelled “GND”) electrically connected to ground, a pair of feedback terminals (labelled “FB1” and “FB2”) that receive respective DC input and output voltage feedbacks,
a current input terminal labelled (“ISET”) that sets the peak discharge and discharging currents of the reversible buck/boost regulator 30, and
an enable terminal (labelled “EN”) electrically connected to a third input/output terminal (labelled “I/O”) of the MCU 32 and which allows the MCU 32 to enable and disable operation of the reversible buck/boost regulator 30.

The inverter 26 is electrically connected to the system bus 44 in parallel with the DC/DC converter 24. The inverter 26 includes:
a positive input terminal (labelled “IN+”) electrically connected to the system bus 44,
a positive output terminal (labelled “OUT+”) and a negative output terminal (labelled “OUT−”),
a serial data terminal (labelled “SDA”) and a serial clock terminal (labelled “SCL”) that are electrically connected to corresponding terminals of the MCU, and
an enable terminal (labelled “EN”) electrically connected to a fourth input/output terminal (labelled “I/O”) of the MCU 32 and which allows the MCU 32 to enable and disable operation of the inverter 26.

When enabled, the inverter 26 may provide an AC signal at the positive output terminal. The AC signal has a suitable waveform with a variable frequency that is determined by the MCU 32. The MCU 32 may control the AC signal by means of serial data communication with the inverter 26.

In addition to the positive input terminal, the invertor 26 may include a negative input terminal not shown in FIG. 2. Alternatively, the negative output terminal may also be used as a negative input terminal.

The LDO regulator 28 is electrically connected to the system bus 44. The LDO regulator 28 includes:
an input terminal (labelled “IN”) electrically connected to the system bus 44,
an output terminal (labelled “OUT”) that provides a regulated voltage supply,
a ground terminal (labelled “GND”) electrically connected to ground, and
an enable terminal (labelled “EN”) electrically connected to the system bus.

In this embodiment, the enable terminal of the LDO regulator 28 works according to positive logic and the input and enable terminals of the LDO regulator are electrically connected to the system bus 44 in parallel. This means that the LDO regulator 28 continuously outputs a regulated voltage from the output terminal unless the system bus voltage is unavailable. The enable terminals of the charging circuit 22, DC/DC converter 24, inverter 26, and reversible buck/boost regulator 30 may use positive or negative logic.

The MCU 32 includes a power supply terminal (labelled “VDD”) electrically connected to the voltage output terminal of the LDO regulator 28 and receives a regulated voltage supply. As noted above, the MCU 32 includes a serial data terminal (labelled “SDA”) and a serial clock terminal (labelled “SCL”) that are electrically connected to corresponding terminals of the charging circuit 22, DC/DC converter 24, inverter 26, and the reversible buck/boost regulator 30. The MCU 32 also includes:
a ground terminal (labelled “GND”) electrically connected to ground,
first, second, third and fourth input/output terminals (labelled “I/O”) that are respectively electrically connected to the enable terminals of the charging circuit 22, DC/DC converter 24, reversible buck/boost regulator 30, and the inverter 26, and
fifth, sixth and seventh input/output terminals (labelled “I/O”) that are respectively electrically connected to the first, second, and third semiconductor switches Q1, Q2 and Q3 for switching them on and off.

When the first semiconductor switch Q1 is switched on, the input terminal of the charging circuit 22 may be electrically connected to the external power source (not shown) if present.

When the second semiconductor switch Q2 is switched on, the voltage input terminal of the DC/DC converter 24 is electrically connected to the system bus 44.

When the third semiconductor switch Q3 is switched on, the voltage output terminal of the DC/DC converter 24 is electrically connected to the induction heater 46 (or other suitable aerosol generator). When the third semiconductor switch Q3 is switched off, the induction heater 46 (or other suitable aerosol generator) is electrically isolated from the voltage output terminal of the DC/DC converter 24. The MCU 32 may control an operation of the inductor heater 46 (or other suitable aerosol generator) by controlling the switching of the third semiconductor switch Q3 using any suitable control algorithm, e.g., pulse width modulation (PWM) or pulse frequency modulation (PFM).

The positive voltage output terminal of the inverter 26 is electrically connected to the superimposing circuit 38. The superimposing circuit 38 is configured to superimpose the AC signal from the inverter 26 on a DC current supplied by the DC/DC converter 24. The superimposing circuit 38 includes an operational amplifier 48. The operational amplifier 48 includes:
a non-inverting input terminal (labelled “+”) electrically connected to the voltage output terminal of the DC/DC converter 24 by means of a first resistor R1 and to a ground connection of the superimposing circuit 38 by means of a first capacitor C1 and a parallel second resistor R2,
an inverting input terminal (labelled “−”) electrically connected to the positive voltage output terminal of the inverter 26,
a positive voltage terminal electrically connected to the voltage output terminal of the DC/DC converter 28 in parallel with the non-inverting input terminal of the operational amplifier 48,
a negative voltage terminal electrically connected to the ground connection of the superimposing circuit 38, and
a voltage output terminal.

A junction point 50 between the inverting input terminal and the positive output terminal of the inverter 26 is electrically connected to the voltage output terminal of the operational amplifier 48 by means of a third resistor R3 and to the ground connection by means of a fourth resistor R4. The negative output terminal of the inverter 26 is also electrically connected to the ground connection of the superimposing circuit 38. The output voltage at the voltage output terminal of the operational amplifier 48 has AC and DC components.

The first switching circuit 34 is a single-pole double-throw (SPDT) switch and includes:
a drain terminal (labelled “D”) electrically connected to the voltage output terminal of the operational amplifier 48,
a first source terminal (labelled “S1”) electrically connected to the positive terminal of the first energy storage device 14,
a second source terminal (labelled “S2”) electrically connected to the positive terminal of the second energy storage device 16,
a select terminal (labelled “SEL”) electrically connected to an eighth input/output terminal (labelled “I/O”) of the MCU 32 and which allows the MCU 32 to selectively control which source terminal is connected to the drain terminal by means of a select signal—i.e., to select if the voltage output terminal of the operational amplifier 48 is electrically connected to the first energy storage device 14 or the second energy storage device 16,
a power supply terminal (labelled “VDD”) electrically connected to the voltage output terminal of the LDO regulator 28 and that receives a regulated voltage supply, and
a ground terminal (labelled “GND”) electrically connected to ground.

The voltage sensing circuit 40 is electrically connected to a junction point 52 between the voltage output terminal of the operational amplifier 48 and the drain terminal of the first switching circuit 34 and is configured to detect the voltage across the first and second energy storage devices 14, 16 when the AC signal is applied. A ninth input/output terminal (labelled “I/O”) of the MCU 32 is electrically connected to the voltage sensing circuit 40, optionally by means of an AC coupling capacitor C2. An additional voltage sensing circuit 54 is configured to detect the input voltage from the external power source (not shown). A tenth input/output terminal (labelled “I/O”) of the MCU 32 is electrically connected to the additional voltage sensing circuit 54.

The current sensing circuit 42 includes a shunt resistor R5 and a current sensing amplifier 56 electrically connected with the shunt resistor. The shunt resistor R5 is electrically connected to a ground connection of the current sensing circuit 42. An eleventh input/output terminal (labelled “I/O”) of the MCU 32 is electrically connected to the current sensing amplifier 56 of the current sensing circuit 42, optionally by means of an AC coupling capacitor C3. An additional operational amplifier 58 may be provided to improve accuracy of the current measurement by stabilising the electrical ground potential.

Each second switching circuit 36A, 36B is a single-pole double-throw (SPDT) switch. One of the second switching circuits 36A includes:
a drain terminal (labelled “D”) electrically connected to the negative terminal of the first energy storage device 14,
a first source terminal (labelled “S1”) electrically connected to the shunt resistor R5 of the current sensing circuit 42,
a second source terminal (labelled “S2”) electrically connected to the ground connection of the current sensing circuit 42,
a select terminal (labelled “SEL”) electrically connected to the eighth input/output terminal (labelled “I/O”) of the MCU 32 and which allows the MCU 32 to selectively control which source terminal is electrically connected to the drain terminal—i.e., to select if the negative terminal of the first energy storage device 14 is electrically connected to the shunt resistor R5 or directly to the ground connection of the current sensing circuit 42,
a power supply terminal (labelled “VDD”) electrically connected to the voltage output terminal of the LDO regulator 28 and that receives a regulated voltage supply, and
a ground terminal (labelled “GND”) electrically connected to ground.

The other one of the second switching circuits 36B includes:
a drain terminal (labelled “D”) electrically connected to the negative terminal of the second energy storage device 16, a first source terminal (labelled “S1”) electrically connected to the ground connection of the current sensing circuit 42,
a second source terminal (labelled “S2”) electrically connected to the shunt resistor R5 of the current sensing circuit 42,
a select terminal (labelled “SEL”) electrically connected to the eighth input/output terminal (labelled “I/O”) of the MCU 32 and which allows the MCU 32 to selectively control which source terminal is electrically connected to the drain terminal—i.e., to select if the negative terminal of the second energy storage device 16 is electrically connected to the shunt resistor R5 or directly to the ground connection of the current sensing circuit 42,
a power supply terminal (labelled “VDD”) electrically connected to the voltage output terminal of the LDO regulator 28 and that receives a regulated voltage supply, and
a ground terminal (labelled “GND”) electrically connected to ground.

The select signal from the eighth input/output terminal of the MCU 32 to the select terminals of the first switching circuit 34 and the pair of second switching circuits 36A, 36B may be low or high. If the select signal is low, the drain terminal of each switching circuit 34, 36A and 36B is electrically connected to the first source terminal (i.e., the “S1” terminal), and if the select signal is high, the drain terminal of each switching circuit 34, 36A and 36B is electrically connected to the second source terminal (i.e., the “S2” terminal). In practice, this means that if the select signal is low:
the voltage output terminal of the operational amplifier 48 of the superimposing circuit 38 is electrically connected to the positive terminal of the first energy storage device 14 through the first switching circuit 34,
the negative terminal of the first energy storage device 14 is electrically connected to the shunt resistor R5 of the current sensing circuit 42 through the second switching circuit 36A, and
the negative terminal of the second energy storage device 16 is electrically connected directly to the ground connection of the current sensing circuit 42 through the other second switching circuit 36B. This circuit configuration allows the AC signal to be applied to the first energy storage device 14 while it is being charged by the second energy storage device 16, i.e., where the output voltage of the operational amplifier 48 of the superimposing circuit 38 with AC and DC components is provided to the positive terminal of the first energy storage device 14.

If the signal is high:
the voltage output terminal of the operational amplifier 48 of the superimposing circuit 38 is electrically connected to the positive terminal of the second energy storage device 16 through the first switching circuit 34,
the negative terminal of the first energy storage device 14 is electrically connected directly to the ground connection of the current sensing circuit 42 through the second switching circuit 36A, and
the negative terminal of the second energy storage device 16 is electrically connected to the shunt resistor R5 of the current sensing circuit 42 through the other second switching circuit 36B. This circuit configuration allows the AC signal to be applied to the second energy storage device 16 while it is being charged by the first energy storage device 14, i.e., where the output voltage of the operational amplifier 48 of the superimposing circuit 38 with AC and DC components is provided to the positive terminal of the second energy storage device 16.

An I²C communication protocol may be used for serial data communication between the MCU 32 and the charging circuit 22, DC/DC converter 24, and inverter 26. Other suitable communication protocols such as SPI or UART may be also used.

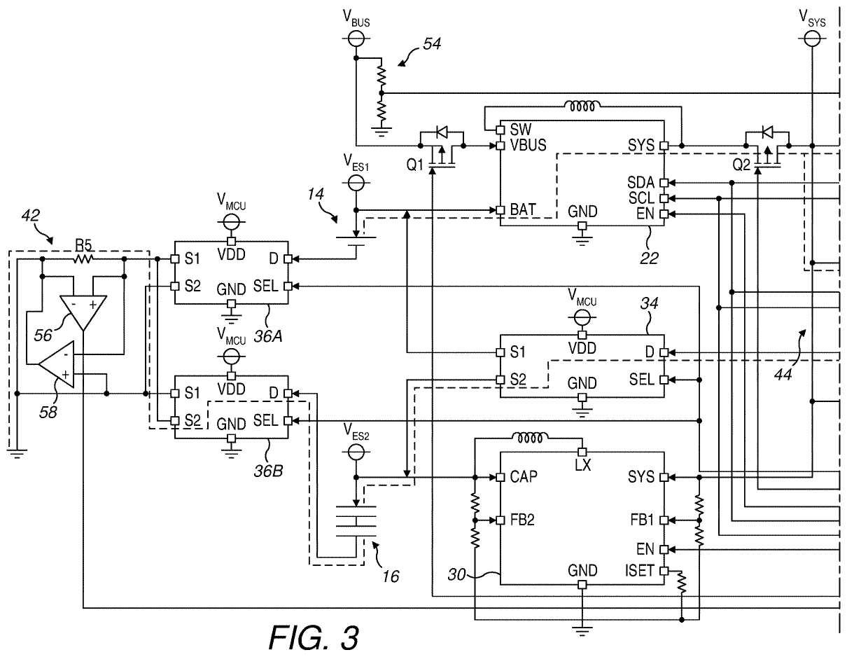

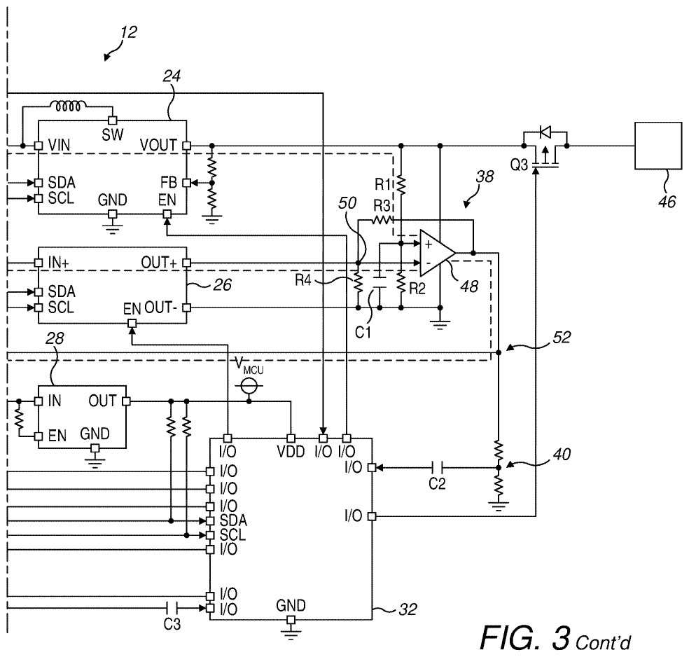

FIG. 3 shows a first step of monitoring a condition of the second energy storage device 16. An AC signal is being applied to the second energy storage device 16 while it is being charged by the first energy storage device 14.

The first semiconductor switch Q1 is switched off to electrically disconnect the external power source (not shown) from the charging circuit 22—e.g., in response to the MCU 32 receiving a low level signal from the additional voltage sensing circuit 54. The second semiconductor switch Q2 is switched on to electrically connect the charging circuit 22 to the system bus 44. The third semiconductor switch Q3 is switched off to electrically disconnect the induction heater 46 from the DC/DC converter 24.

The charging circuit 22 is disabled by the MCU 32 to prevent the first energy storage device 14 from being charged. More particularly, the MCU 32 sends a disable signal from the first input/output terminal to the enable terminal of the charging circuit 22.

The reversible buck/boost regulator 30 is disabled by the MCU 32 to prevent the second energy storage device 16 from being discharged. More particularly, the MCU 32 sends a disable signal from the third input/output terminal to the enable terminal of the reversible buck/boost regulator 30.

The first energy storage device 14 is discharged to supply DC current to the system bus 44 through the charging circuit 22 and the second semiconductor switch Q2, and hence to the voltage input terminal of the DC/DC converter 24 and the inverter 26. The DC/DC converter 24 is enabled by the MCU 32 to provide a DC current from the voltage output terminal to the non-inverting input terminal of the operational amplifier 48 of the superimposing circuit 38. More particularly, the MCU 32 sends an enable signal from the second input/output terminal to the enable terminal of the DC/DC converter 24.

At the same time, the inverter 26 is also enabled by the MCU and provides an AC signal to the superimposing circuit 38—i.e., to the inverting terminal of the operational amplifier 48. More particularly, the MCU 32 sends an enable signal from the fourth input/output terminal to the enable terminal of the inverter 26. The AC signal from the inverter 26 is superimposed on the DC current from the DC/DC converter 24 by the superimposing circuit 38 so that the output of the superimposing circuit—i.e., the output voltage of the operational amplifier 48—has both AC and DC components.

The select signal from the eighth input/output terminal of the MCU 32 to the select terminals of the first switching circuit 34 and the pair of second switching circuits 36A, 36B is high so that the output voltage of the operational amplifier 48 is provided to the positive terminal of the second energy storage device 16 to charge it. The negative terminal of the second energy storage device 16 is electrically connected to the shunt resistor R5 of the current sensing circuit 42. The negative terminal of the first energy storage device 14, which is discharging, is electrically connected directly to the ground connection of the current sensing circuit 42. While the second energy storage device 16 is being charged, voltage and current measurements are detected by the voltage and current sensing circuits 40, 42 and provided to the MCU 32.

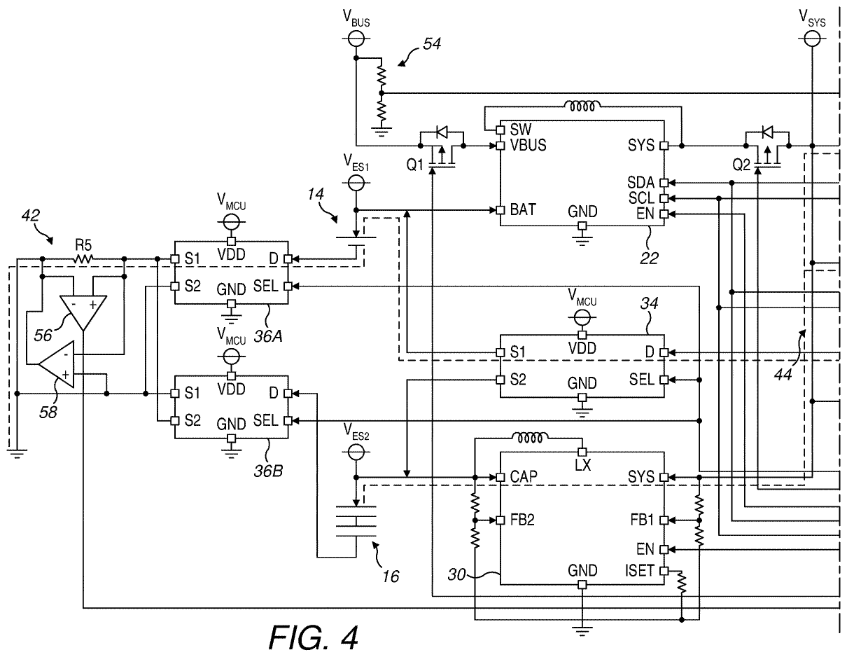

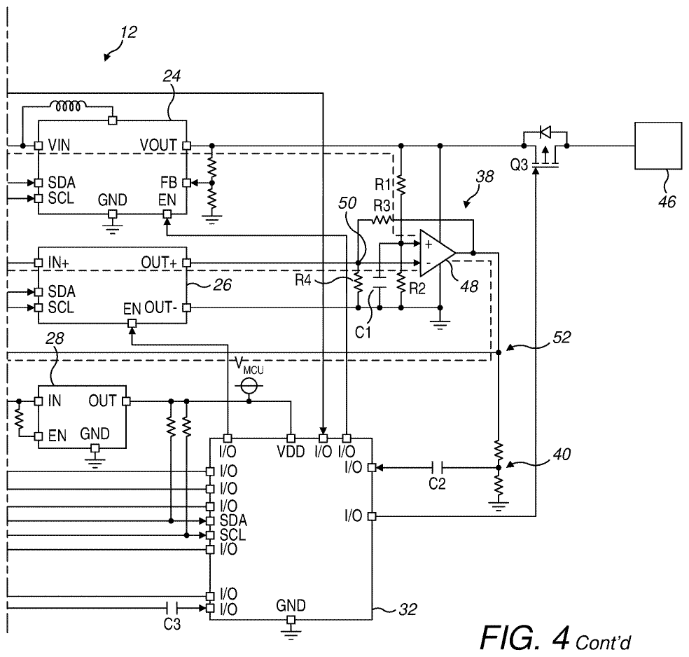

FIG. 4 shows a second step of monitoring a condition of the first energy storage device 14. An AC signal is being applied to the first energy storage device 14 while it is being charged by the second energy storage device 16.

The first semiconductor switch Q1 is switched off to electrically disconnect the external power source (not shown) from the charging circuit 22—e.g., in response to the MCU 32 receiving a low level signal from the additional voltage sensing circuit 54. The second semiconductor switch Q2 is switched off to electrically disconnect the charging circuit 22 from the system bus 44. The third semiconductor switch Q3 is switched off to electrically disconnect the induction heater 46 from the DC/DC converter 24.

The charging circuit 22 is disabled by the MCU 32. More particularly, the MCU 32 sends a disable signal from the first input/output terminal to the enable terminal of the charging circuit 22.

The reversible buck/boost regulator 30 is enabled by the MCU 32 and operated to supply DC current to the system bus 44, and hence to the voltage input terminal of the DC/DC converter 24, by discharging the second energy storage device 16. More particularly, the MCU 32 sends an enable signal from the third input/output terminal to the enable terminal of the reversible buck/boost regulator 30. The DC/DC converter 24 is enabled by the MCU 32 to provide a DC current from the voltage output terminal to the non-inverting input terminal of the operational amplifier 48 of the superimposing circuit 38. More particularly, the MCU 32 sends an enable signal from the second input/output terminal to the enable terminal of the DC/DC converter 24.

At the same time, the inverter 26 is also enabled by the MCU 32 and provides an AC signal to the superimposing circuit 38—i.e., to the inverting input terminal of the operational amplifier 48. More particularly, the MCU 32 sends an enable signal from the fourth input/output terminal to the enable terminal of the inverter 26. The AC signal from the inverter 26 is superimposed on the DC current from the DC/DC converter 24 by the superimposing circuit 38 so that the output of the superimposing circuit—i.e., the output voltage of the operational amplifier 48—has both AC and DC components.

The select signal from the eighth input/output terminal of the MCU 32 to the select terminals of the first switching circuit 34 and the pair of second switching circuits 36A, 36B is low so that the output voltage of the operational amplifier 48 is provided to the positive terminal of the first energy storage device 14 to charge it. The negative terminal of the first energy storage device 14 is electrically connected to the shunt resistor R5 of the current sensing circuit 42. The negative terminal of the second energy storage device 16, which is discharging, is electrically connected directly to the ground connection of the current sensing circuit 42. While the first energy storage device 14 is being charged, voltage and current measurements are detected by the voltage and current sensing circuits 40, 42 and provided to the MCU 32.

An active monitoring process may be initiated by the MCU 32 at the end of a vaping session, for example in the final 10-20 seconds when the induction heater 46 is switched off. The monitoring process may comprise carrying out the first step to obtain a condition of the second energy storage device 16 followed by the second step to obtain a condition of the first energy storage device 14, or vice versa.

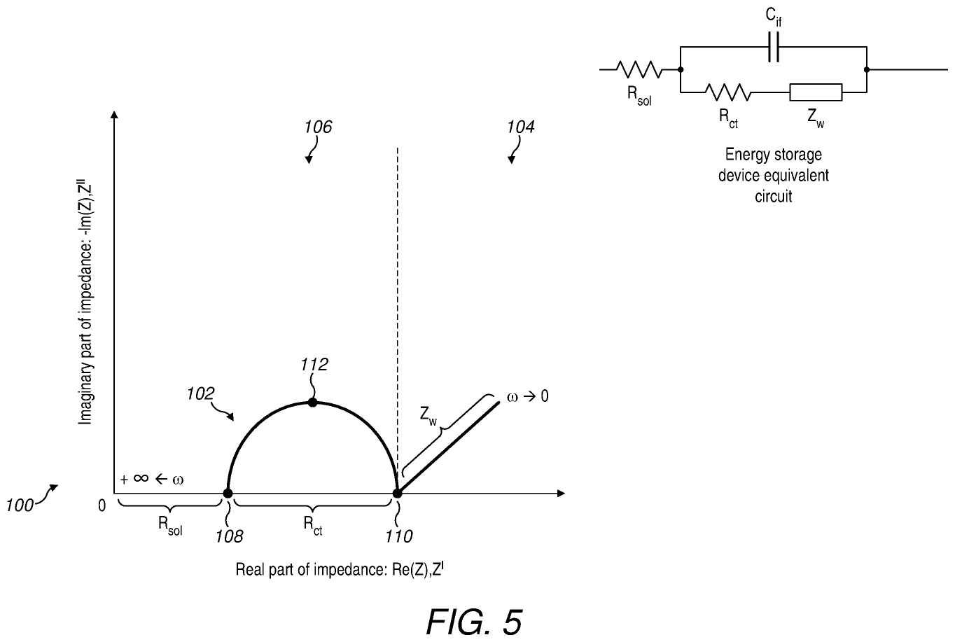

To obtain the condition of each energy storage device, the MCU 32 uses the voltage and current measurements obtained during the first and second steps of the monitoring process. In particular, the voltage and current measurements are used to estimate or determine one or more electrical parameters of each energy storage device. The one or more electrical parameters are calculated by the MCU 32 mainly according to a Nyquist plot (or Cole-Cole plot). An example of a Nyquist plot 100 is shown in FIG. 5. The imaginary part of the complex impedance Z″ (or −Im(Z)) is the vertical axis and the real part of the complex impedance Z′ (or Re(Z)) is the horizontal axis. A bold line 102 is an aggregation of the complex impedances corresponding to each frequency of the AC signal that is applied across the positive and negative electrodes of the respective energy storage device. As noted above, it will be understood that the Nyquist plot shown in FIG. 5 may be considered to be an idealised frequency response that is intended to illustrate the electrical parameters of the energy storage device. In practice, the Nyquist plot derived for an actual energy storage device may deviate quite significantly from this idealised frequency response but, as will be understood by one of ordinary skill in the art, the Nyquist plot will still retain the same general characteristics and it will be possible to distinguish between a substance transfer process region, which may be generally linear, and a charge transfer process recess, which may be generally semi-circular or curved, for example. The frequency of the AC signal may be swept by the inverter 26 across a wide frequency range (e.g., 100 Hz to 1 kHz) one or more times. Alternatively, the frequency may be swept across several narrower frequency ranges, or one or more different frequencies may be used to construct the Nyquist plot as described above. The MCU 32 calculates concrete values of the complex impedances corresponding to each frequency based on the input signal that is provided to the ninth input/output terminal that is electrically connected to the voltage sensing circuit 40 and the input signal that is provided to the eleventh input/output terminal that is electrically connected to the current sensing circuit 42, and in particular to the output terminal of the current sensing amplifier 56. Because these input signals are AC signals, the MCU 32 may calculate the real and imaginary parts of the complex impedance Z′, Z″ by dividing the input signal from the voltage sensing circuit 40 by the input signal from the current sensing circuit 42. More particularly, the MCU 32 may plot a dot corresponding to the calculation results of the real and imaginary parts of the complex impedance Z′, Z″ for a particular frequency of the AC signal on a diagram. As a result of frequency sweeps within the preferred frequency range(s), the individual dots will form the bold line 102. In the example of the Nyquist plot shown in FIG. 5, the right-hand part corresponds to a low frequency and the left-hand part corresponds to a high frequency—i.e., the bold line 102 is plotted from right to left as the frequency of the AC signal is swept from a low frequency to a high frequency and is plotted from left to right as the frequency of the AC signal is swept from a high frequency to a low frequency.

The example of the Nyquist plot shown in FIG. 5 may be divided into two separate regions—namely a substance transfer process region 104 and a charge transfer process region 106. The bold line 102 may be substantially linear in the substance transfer process region 104 and may be substantially semi-circular in the charge transfer process region 106 as shown. The length of the bold line 102 in the substance transfer process region 104 corresponds to a diffusion resistance Z_{W} that is shown in FIG. 5 as part of a real equivalent energy storage device circuit. The substance transfer process region 104 corresponds to a low frequency range (e.g., less than about 1 Hz) and measurements in this region may not be preferred because it will increase the overall measurement time. The substance transfer process region 104 may therefore be of less relevance when trying to estimate or determine one or more electrical parameters of the energy storage device. Measurements may therefore be focused on the charge transfer process region 106 with higher frequencies. The semi-circular part of the bold line 102 may have a first zero crossing point 108 and a second zero crossing point 110. The second zero crossing point 110 is positioned on the boundary between the substance transfer process region 104 and the charge transfer process region 106. The distance between the origin and the first zero crossing point 108 corresponds to a solution resistance Rₛₒₗ of the equivalent circuit of the energy storage device, and a distance between the first and second zero crossing points 108, 110—i.e., the diameter of the semi-circular part of the bold line 102—corresponds to a charge transfer resistance R_{ct}. The sum of the solution resistance Rₛₒₗ and the charge transfer resistance R_{ct}—i.e., the distance between the origin and the second zero crossing point 110—corresponds to the internal resistance of the energy storage device. In the equivalent circuit of the energy storage device, C_{if} is the interface capacitance of the energy storage device.

The imaginary part of the complex impedance Z″ and the frequency f at the highest point 112 in the vertical axis may be used to calculate the interface capacitance C_{if} of the respective energy storage device from:

$${C}_{if} = \frac{1}{2 π f \cdot \vert {Z}^{″} \vert}$$

The solution resistance Rₛₒₗ may be estimated or determined from the first crossing point 108.

The charge transfer resistance R_{ct} of the energy storage device may be estimated or determined from the first and second zero crossing points 108, 110 or from:

$${R}_{c t} = \frac{1}{( {ω}_{max} \cdot {C}_{if} )}$$

where ωₘₐₓ is the angular frequency at the highest point 112.

One or more of the interface capacitance C_{if}, the solution resistance Rₛₒₗ, and the charge transfer resistance R_{ct}, for example, may be used to determine a condition of the respective energy storage device. For example, the interface capacitance C_{if} may be compared against one or more thresholds. If the interface capacitance C_{if} is less than a first threshold, it may be indicative that the energy storage device needs to be replaced and the condition of the energy storage device may be flagged as “consider replacement”. If the interface capacitance C_{if} is less than a second threshold, which second threshold is lower than the first threshold, it may be indicative that the energy storage device is not suitable for operation and it may be advisable to disable the aerosol generating device 2. The condition of the energy storage device may be flagged as “not suitable for operation” and the MCU 32 may stop further operation of the aerosol generating device 2. The solution resistance Rₛₒₗ and the charge transfer resistance R_{ct} may be compared against one or more thresholds in a similar way. If the faulty energy storage device is detachable, operation may be stopped until it has been removed and replaced with another energy storage device.

It should be noted again that a wide frequency range that includes the first zero crossing point 108 may not be essential for estimating or determining the condition of the energy storage device. Only more limited frequency ranges around the second zero crossing point 110 or the highest point 112 may be required in some cases.

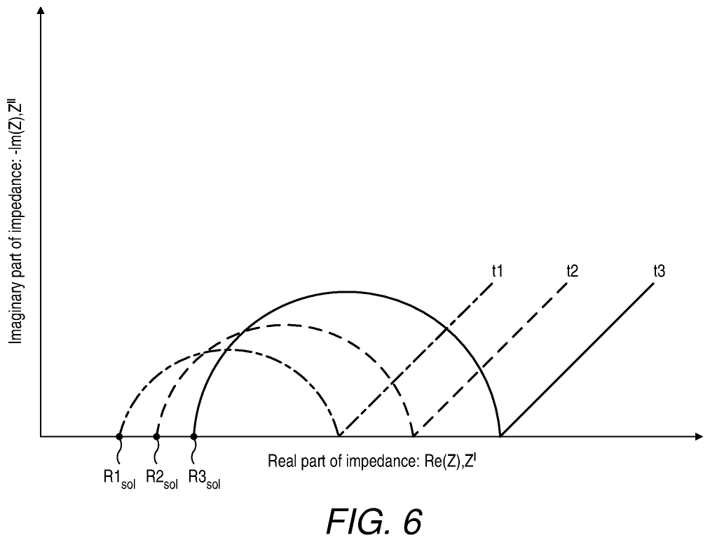

FIG. 6 shows an example of how the Nyquist plot for a particular energy storage device might vary with the number of charging cycles. It shows three separate Nyquist plots for the particular energy storage device obtained at different times, e.g., at the end of three separate vaping sessions that may be separated by several weeks. As already noted above, it will be understood that the Nyquist plots shown in FIG. 6 may be considered to be idealised frequency responses that are intended to illustrate the changes in the electrical parameters of the energy storage device as it ages, or more particularly, assuming that the aerosol generating device is being regularly used, as a function of the number of charging cycles of the energy storage device. In practice, the Nyquist plots derived for an actual energy storage device may deviate quite significantly from these idealised frequency responses. The Nyquist plot labelled “t1” has been obtained from an initial vaping session when the energy storage device has undergone n1 charging cycles (e.g., when the energy storage device was new and where n1 may be zero or very close to zero). The Nyquist plot labelled “t2” has been obtained from a later vaping session where the energy storage device has undergone n2 charging cycles (where n2>n1). The Nyquist plot labelled “t3” has been obtained from a still later vaping session where the energy storage device has undergone n3 charging cycles (where n3>n2). A comparison between the different Nyquist plots, or between one or more electrical parameters obtained from the different Nyquist plots, may be used to monitor the degradation of the particular energy storage device as it ages, for example. In particular, it can be seen that the respective solution resistances (or ohmic internal resistances) R1ₛₒₗ, R2ₛₒₗ, and R3ₛₒₗ, increase with the number of charging cycles as the energy storage devices ages (i.e., where R3ₛₒₗ>R2ₛₒₗ>R1ₛₒₗ). It can also be seen that both the internal resistance and the imaginary part of the complex impedance Z″ at the highest point in the vertical axis increase with the number of charging cycles. It therefore follows that the interface capacitance C_{if} decreases with the number of charging cycles.

An active monitoring process similar to that described above may be used if an energy storage device is detachable or removable—i.e., if it may be removed from, and inserted into, the aerosol generating device 2 by a user. In this monitoring process, an AC signal may be applied to the energy storage device in response to it being electrically connected to the aerosol generating device. The AC signal may be superimposed on a DC current that may be provided by discharging another energy storage device of the aerosol generating device, or by an external power source. For example, in the circuit 12 shown in FIG. 2, the first energy storage device 14 may be detachable and its condition may be estimated or determined when it is electrically connected to the external circuit by discharging the second energy storage device 16 as described above. This monitoring method may be used to check if the condition of the first energy storage device 14 is acceptable before starting operation of the aerosol generating device 2, i.e., if one or more electrical parameters of the first energy storage device 14 are within acceptable limits, or are above or below one or more suitable thresholds, for example.

Although exemplary embodiments have been described in the preceding paragraphs, it should be understood that various modifications may be made to those embodiments without departing from the scope of the appended claims. Thus, the breadth and scope of the claims should not be limited to the above-described exemplary embodiments.

Any combination of the above-described features in all possible variations thereof is encompassed by the present disclosure unless otherwise indicated herein or otherwise clearly contradicted by context.

Unless the context clearly requires otherwise, throughout the description and the claims, the words “comprise”, “comprising”, and the like, are to be construed in an inclusive as opposed to an exclusive or exhaustive sense; that is to say, in the sense of “including, but not limited to”.

1. A method of monitoring an aerosol generating system comprising a first energy storage device adapted to supply power to generate an aerosol, the method comprising monitoring a condition of the first energy storage device by:
supplying a direct current DC current to the first energy storage device to charge the first energy storage device;
applying an alternating current AC signal to the first energy storage device, wherein the AC signal is superimposed on the DC current being supplied to the first energy storage device;
using at least one of a voltage measurement or a current measurements obtained in response to the applied AC signal to estimate or determine one or more electrical parameters of the first energy storage device; and
using the one or more electrical parameters to estimate or determine a condition of the first energy storage device.

2. A method according to claim 1, wherein the aerosol generating system further comprises a second energy storage device, the DC current being supplied to the first energy storage device from the second energy storage device.

3. A method according to claim 1, wherein the aerosol generating system further comprises a second energy storage device, the method comprising monitoring a condition of the second energy storage device by:
supplying a DC current to the second energy storage device to charge the second energy storage device;
applying an AC signal to the second energy storage device, wherein the AC signal is superimposed on the DC current being supplied to the second energy storage device;
using at least one of voltage and current measurements obtained in response to the applied AC signal to estimate or determine one or more electrical parameters of the second energy storage device; and
using the one or more electrical parameters to estimate or determine a condition of the second energy storage device.

4. A method according to claim 3, wherein the AC signal is applied to the first and second energy storage devices sequentially.

5. A method according to claim 1, further comprising operating the aerosol generating system in a heating mode and a non-heating mode, wherein the AC signal is applied to the first energy storage device when the aerosol generating system is in the non-heating mode.

6. A method according to claim 1, wherein the one or more electrical parameters are estimated or determined using a frequency response plot.

7. A method of monitoring a detachable energy storage device in response to the detachable energy storage device being electrically connected to an aerosol generating system for the first time by:
applying an AC signal to the just-connected energy storage device;
using at least one of a voltage measurement or a current measurements obtained in response to the applied AC signal to estimate or determine one or more electrical parameters of the energy storage device; and
using the one or more electrical parameters to estimate or determine an initial condition of the energy storage device.

8. A method according to claim 7, further comprising supplying a DC current to the just-connected energy storage device, and wherein the AC signal is superimposed on the DC current.

9. An aerosol generating system comprising:
a first energy storage device;
an inverter electrically connected to the first energy storage device and configured to apply an AC signal to the first energy storage device;
a superimposing circuit electrically connected to the inverter and the first energy storage device, wherein the superimposing circuit is configured to superimpose the AC signal on a DC current that is supplied to the first energy storage device to charge the first energy storage device; and
a controller configured to:
use at least one of a voltage measurement or a current measurements obtained in response to the applied AC signal to estimate or determine one or more electrical parameters of the first energy storage device; and
use the one or more electrical parameters to estimate or determine a condition of the first energy storage device.

10. An aerosol generating system according to claim 9, further comprising a second energy storage device, wherein the inverter is electrically connected to the second energy storage device and configured to apply an AC signal to the second energy storage device, and the superimposing circuit is electrically connected to the second energy storage device and configured to superimpose the AC signal on a DC current that is supplied to the second energy storage device to charge the second energy storage device.

11. An aerosol generating system according to claim 10, further comprising a first switching circuit electrically connected between the superimposing circuit and the first and second energy storage devices configured to selectively connect the output of the superimposing circuit to one of the first and second energy storage devices.

12. An aerosol generating system according to claim 11, wherein the first switching circuit comprises a single-pole double-throw switching circuit.

13. An aerosol generating system according to claim 11, further comprising a voltage sensing circuit configured to measure the voltage across the first or second energy storage device when the AC signal is applied, wherein the voltage sensing circuit is electrically connected between the output of the superimposing circuit and the first switching circuit.

14. An aerosol generating system according to claim 10, further comprising a current sensing circuit configured to measure the current through the first or second energy storage device when the AC signal is applied.

15. An aerosol generating system according to claim 14, wherein the current sensing circuit includes a shunt resistor and a current sensing amplifier electrically connected with the shunt resistor, wherein the aerosol generating system further comprises a plurality of second switching circuits, each second switching circuit being electrically connected to a respective one of the first and second energy storage devices and configured to selectively connect the respective one of the first and second energy storage devices directly to ground, or to ground via the shunt resistor of the current sensing circuit.

16. An aerosol generating system according to claim 15, wherein each of the second switching circuits comprises a single-pole double-throw switching circuit.

17. (canceled)

18. (canceled)
